(19) United States
(12) Patent Application Publication
(10) Pub. No.: US 2026/0190634 A1
(43) Pub. Date: Jul. 2, 2026

(54) DISPLAY APPARATUS HAVING LIGHT-EMITTING DEVICES

(71) Applicant: LG Display Co., Ltd., Seoul (KR)

(72) Inventors: Hee Su BYEON, Paju-si (KR); Yeon Suk KANG, Paju-si (KR); Sae Mi PARK, Paju-si (KR)

(73) Assignee: LG Display Co., Ltd., Seoul (KR)

(21) Appl. No.: 19/224,287

(22) Filed: May 30, 2025

(30) Foreign Application Priority Data
Dec. 31, 2024 (KR) 10-2024-0202969

(51) Int. Cl. H10K 59/122; H10K 59/80

(52) U.S. Cl. CPC H10K 59/122; H10K 59/8792

(57) ABSTRACT

A display apparatus includes light-emitting devices disposed on emission areas of a device substrate. The device substrate can include a first surface toward the light-emitting devices and a second surface opposite to the first surface. A diode substrate can be disposed on the second surface of the device substrate. Light-emitting diodes can be disposed side by side on a surface of the diode substrate toward the device substrate. The light-emitting diodes can be disposed between the emission areas. Thus, in the display apparatus, the luminance of an image can be improved.

### CROSS-REFERENCE TO RELATED APPLICATIONS

This application claims priority to Korean Patent Application No. 10-2024-0202969, filed in the Republic of Korea on Dec. 31, 2024, the entire contents of which is hereby expressly incorporated by reference as if fully set forth herein into the present application.

### BACKGROUND OF THE INVENTION

### Field of the Invention

The present disclosure relates to a display apparatus in which light-emitting devices are disposed on the emission areas of a device substrate.

### Discussion of the Related Art

Generally, a display apparatus provides an image to a user and can include light-emitting devices. Each of the light-emitting devices can emit light displaying a specific color. For example, each of the light-emitting devices can include a first electrode, a light-emitting unit and a second electrode, which are sequentially stacked.

The light-emitting devices can be disposed on the emission areas of a device substrate. Each of the emission areas can realize a different color from an adjacent emission area. For example, the emission areas can include a blue emission area for realizing blue color, a red emission area for realizing red color, and a green emission area for realizing green color.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of improving the overall luminance of the image.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a first substrate. Light-emitting diodes are disposed on the first substrate. The light-emitting diodes are disposed side by side in a first direction. A second substrate is disposed on the light-emitting diodes. The second substrate includes emission areas. Light-emitting devices are disposed on the second substrate. The light-emitting devices overlap the emission areas. The emission areas are disposed side by side in the first direction and a second direction that is perpendicular to the first direction. Each of the light-emitting diodes is disposed between the emission areas that are adjacent to each other in the first direction.

According to aspects of the present disclosure, each of the emission areas can realize a different color from the adjacent emission area disposed in the first direction.

According to aspects of the present disclosure, the second substrate can include substrate holes disposed between the emission areas. Each of the light-emitting diodes can overlap one of the substrate holes.

According to aspects of the present disclosure, a substrate adhesive layer can be disposed between the light-emitting devices and the second substrate. The substrate holes can be filled by the substrate adhesive layer.

According to aspects of the present disclosure, insulating patterns can be disposed on a side-wall of each substrate hole. Each of the insulating patterns can include a light-blocking material.

According to aspects of the present disclosure, a planarization layer can be disposed between the second substrate and the light-emitting devices. The planarization layer can include at least one trench disposed between the emission areas. Each of the light-emitting diodes can overlap the at least one trench.

According to aspects of the present disclosure, color filters can be disposed on the light-emitting devices. Each of the color filters can overlap one of the emission areas. Each of the color filters can be spaced apart from the adjacent color filter disposed in the first direction.

According to aspects of the present disclosure, a black matrix can be disposed between the color filters that are disposed adjacent to each other in the first direction. The black matrix can include penetrating holes overlapping with the light-emitting diodes.

According to aspects of the present disclosure, conductive patterns can be disposed between the second substrate and the light-emitting devices. At least one of the conductive patterns can include an opening overlapping with the light-emitting diodes.

According to aspects of the present disclosure, device driving circuits can be disposed between the second substrate and the light-emitting devices. Each of the device driving circuits can be electrically connected to one of the light-emitting devices. The conductive patterns can be insulated from the device driving circuits.

According to aspects of the present disclosure, diode driving parts can be disposed between the first substrate and the second substrate. The diode driving parts can be spaced apart from the light-emitting diodes. Each of the diode driving parts can be electrically connected to one of the light-emitting diodes and one of the conductive patterns.

According to aspects of the present disclosure, the second substrate can include connection holes overlapping with the conductive patterns. Each of the conductive patterns can be connected to the corresponding diode driving part passing through one of the connection holes.

According to aspects of the present disclosure, a color displayed by light emitted from each light-emitting diode can be different from colors displayed in the emission areas.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to one or more embodiments of the present disclosure;

FIG. 2 is an enlarged view of K region in FIG. 1;

FIG. 3 is a view showing a circuit of a pixel area in the display apparatus according to one or more embodiments of the present disclosure;

FIG. 4 is a view taken alone line I-I′ of FIG. 2; and

FIGS. 5 to 16 are views showing the display apparatus according to other embodiment(s) of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element and may not define order or sequence. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

Also, unless ‘directly’ is used, the terms “connected” and “coupled” can include that two components are “connected” or “coupled” through one or more other components located between the two components. Further, the term “can” fully encompasses all the meanings and coverages of the term “may” and vice versa.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Various embodiments of the present disclosure will now be discussed below referring to the drawings. All the components of each display apparatus according to all embodiments of the present disclosure are operatively coupled and configured.

### EMBODIMENTS

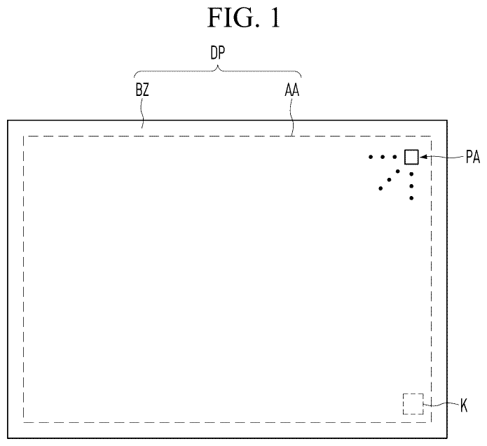

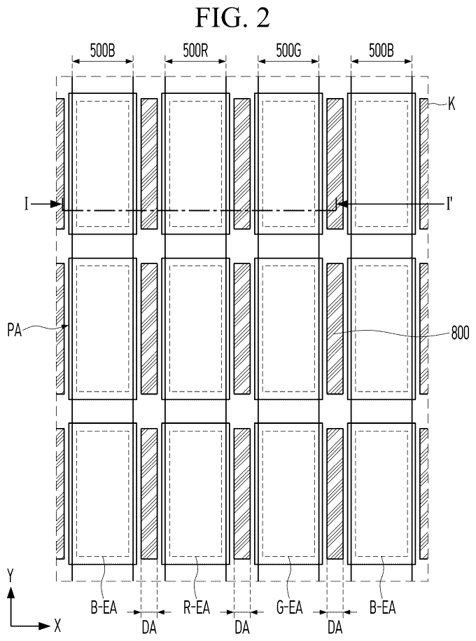

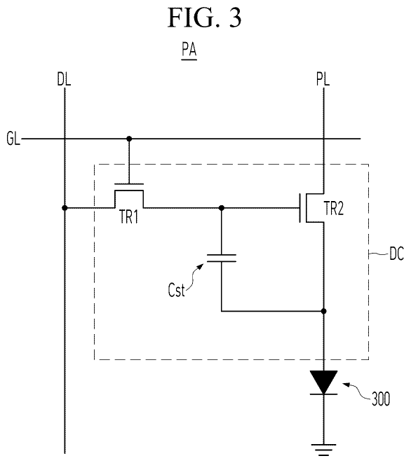

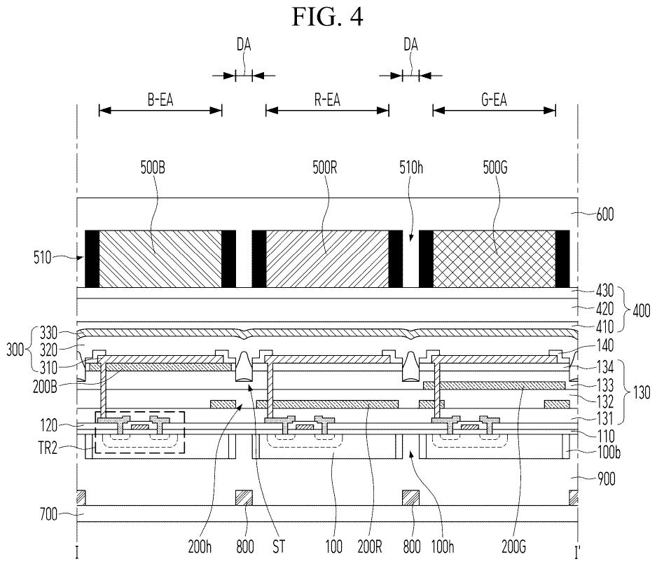

FIG. 1 is a view schematically showing a display apparatus according to one or more embodiments of the present disclosure. FIG. 2 is an enlarged view of K region in FIG. 1. FIG. 3 is a view showing a circuit of a pixel area in the display apparatus according to the embodiments of the present disclosure. FIG. 4 is a view taken alone line I-I′ of FIG. 2.

Referring to FIGS. 1 to 4, the display apparatus according to one or more embodiments of the present disclosure can include a display panel DP. The display panel DP can generate an image provided to a user. For example, pixel areas PA can be disposed within the display panel DP. Each of the pixel areas PA can realize a specific color according to signal applied through signal wirings GL, DL and PL. For example, each of the pixel area PA can include a device driving circuit DC electrically connected to the signal wirings GL, DL and PL, and a light-emitting device 300 electrically connected to the device driving circuit DC.

The signal wirings GL, DL and PL can include a gate line GL applying a gate signal, a data line DL applying a data signal, and a power voltage supply line PL supplying a power voltage. For example, the device driving circuit DC can supply a driving current corresponding to the data signal to the light-emitting device 300 according to the gate signal using the power voltage. The driving current supplied to the light-emitting device 300 by the device driving circuit DC can be maintained for one frame. For example, the device driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first well region, a first drain region, a first source region, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can include a second well region, a second drain region, a second source region, a second gate electrode, a second drain electrode and a second source electrode. For example, the second gate electrode can be electrically connected to the first source electrode, and the second drain electrode can be electrically connected to the power voltage supply line PL.

A voltage of a signal applied to the second gate electrode can be maintained by the storage capacitor Cst for one frame. The storage capacitor Cst can have a stacked structure of capacitor electrodes. For example, the storage capacitor Cst can have a stacked structure of a first capacitor electrode electrically connected to the second gate electrode and a second capacitor electrode electrically connected to the second source electrode.

The device driving circuit DC of each pixel area PA can be supported by a device substrate 100. The device substrate 100 can include various materials. For example, the device substrate 100 can be a wafer made of a semiconductor material, such as silicon. The device driving circuit DC of each pixel area PA can include a region disposed in the device substrate 100. For example, the first well region, the first drain region, the first source region, the second well region, the second drain region and the second source region of each pixel area PA can be formed inside the device substrate 100.

At least one insulating layer 110, 120, 130 and 140 for preventing unintended electrical connection can be disposed on the device substrate 100. For example, a gate insulating layer 110, an interlayer insulating layer 120, a device planarization layer 130 and fences 140 can be disposed on the device substrate 100.

The gate insulating layer 110 can be disposed close the device substrate 100. The second gate electrode of each pixel area PA can be insulated from the second well region of the corresponding pixel area PA. For example, an upper surface of the device substrate 100 toward the second gate electrode of each pixel area PA can be covered by the gate insulating layer 110.

The interlayer insulating layer 120 can be disposed on the gate insulating layer 110. The second drain electrode and the second source electrode of each pixel area PA can be insulated from the second gate electrode of the corresponding pixel area PA by the interlayer insulating layer 120. For example, the first gate electrode and the second gate electrode of each pixel area PA can be disposed between the gate insulating layer 110 and the interlayer insulating layer 120.

The device planarization layer 130 can be disposed on the interlayer insulating layer 120. A thickness difference due to the device driving circuit DC of each pixel area PA can be removed by the device planarization layer 130. For example, the first drain electrode, the first source electrode, the second drain electrode and the second source electrode of each pixel area PA disposed on the interlayer insulating layer 120 can be covered by the device planarization layer 130.

The device planarization layer 130 can include a material having a higher fluidity than the gate insulating layer 110 and the interlayer insulating layer 120. For example, the gate insulating layer 110 and the interlayer insulating layer 120 can include an inorganic insulating material, and the device planarization layer 130 can include an organic insulating material. An upper surface of the device planarization layer 130 opposite to the device substrate 100 can be flat.

The light-emitting device 300 of each pixel area PA can be disposed on the upper surface of the device planarization layer 130. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked on the device planarization layer 130.

The first electrode 310 and the second electrode 330 can include a conductive material. The second electrode 330 can include a different material from the first electrode 310. For example, the first electrode 310 can be a transparent electrode made of a transparent conductive material, such as ITO and IZO, and the second electrode 330 can be a translucent electrode in which a metal, such as silver (Ag) and magnesium(Mg) is thinly formed. The light-emitting unit 320 can generate light having luminance corresponding to a voltage difference between the first electrode 310 and the second electrode 330. For example, the light-emitting unit 320 can include at least one emission material layer (EML).

The fences 140 can be disposed on the device planarization layer 130. The fences 140 can include an insulating material. For example, the fences 140 can be an inorganic insulating layer made of an inorganic insulating material. An edge of the first electrode 310 in each pixel area PA can be covered by one of the fences 140. The first electrode 310 of each pixel area PA can be insulated from the first electrode 310 of adjacent pixel area PA by the fences 140. For example, an emission area B-EA, R-EA and G-EA from which light is generated can be defined in each pixel area by the fences 140. The light-emitting unit 320 of each pixel area PA can be in direct contact with the first electrode 310 and the second electrode 330 of the corresponding pixel area PA in the emission area B-EA, R-EA and G-EA of the corresponding pixel area. For example, in the display apparatus according to the embodiment of the present disclosure, the device substrate 100 can includes the emission areas B-EA, R-EA and G-EA defined by the fences 140, and the light-emitting device 300 of each pixel area PA can overlap one of the emission areas B-EA, R-EA and G-EA. Thus, in the display apparatus according to the embodiment of the present disclosure, the image provided to the user can be realized by the light emitted from the emission areas B-EA, R-EA and G-EA of the device substrate 100.

The first electrode 310 of each pixel area PA can be in direct contact with the second source electrode of the corresponding pixel area PA. For example, the first electrode 310 of each pixel area PA can penetrate the device planarization layer 130. A signal applied to the second electrode 330 of each pixel area PA can be the same as a signal applied to the second electrode 330 of adjacent pixel area PA. For example, the second electrode 330 of each pixel area PA can be electrically connected to the second electrode 330 of adjacent pixel area PA. Thus, in the display apparatus according to the embodiment of the present disclosure, the luminance of the light emitted from the emission area B-EA, R-EA and G-EA of each pixel area PA can be determined by the data signal applied to the device driving circuit DC of the corresponding pixel area PA.

The image generated by the pixel areas PA can include various colors. The light emitted from the emission area B-EA, R-EA and G-EA of each pixel area PA can display a specific color. For example, the emission area B-EA, R-EA and G-EA of each pixel area PA can be one of a blue emission area B-EA emitting blue light, a red emission area R-EA emitting red light, and a green emission area G-EA emitting green light. The emission areas B-EA, R-EA and G-EA of the pixel areas PA can be disposed side by side in a first direction X and a second direction Y perpendicular to the first direction Y. The emission area B-EA, R-EA and G-EA of each pixel area PA can realize a different color from the emission area B-EA, R-EA and G-EA of the pixel area PA adjacent in the first direction X. For example, the blue emission area B-EA, the red emission area R-EA and the green emission area G-EA can be repeated in the first direction X. The emission area B-EA, R-EA and G-EA of each pixel area PA can realize a same color as the emission area B-EA, R-EA and G-EA of the pixel area PA adjacent in the second direction Y.

The light generated by the light-emitting unit 320 of each pixel area PA can display a same color as the light generated by the light-emitting unit 320 of adjacent pixel area PA. For example, the light-emitting unit 320 of each pixel area PA can generate white light. The light-emitting unit 320 of each pixel area PA can be formed simultaneously with the light-emitting unit 320 of adjacent pixel area PA. A micro-cavity structure to emit light having a specific wavelength can be formed in the emission area B-EA, R-EA and G-EA of each pixel area PA. For example, a reflective electrode 200B, 200R and 200G can be disposed between the device driving circuit DC and the first electrode 310 of each pixel area PA. A color displayed by the light emitted from the emission area B-EA, R-EA and G-EA of each pixel area PA can be determined by the location of the reflective electrode 200B, 200R and 200G on the corresponding pixel area PA. For example, the device planarization layer 130 can include a first planarization layer 131 on the interlayer insulating layer 120, a second planarization layer 132 covering a red reflective electrode 200R of the red emission area R-EA on the first planarization layer 131, a third planarization layer 133 covering a green reflective electrode 200G of the green emission area G-EA on the second planarization layer 132, and a fourth planarization layer 134 on the third planarization layer 133. A side surface of a blue reflective electrode 200B of the blue emission area B-EA on the third planarization layer 133 can be surrounded by the fourth planarization layer 134. For example, an upper surface of the blue reflective electrode 200B opposite to the device substrate 100 can be in direct contact with the first electrode 310 disposed on the blue emission area B-EA.

A separating trench ST can be disposed between the fences 140. The separating trench ST can have a groove shape from which a portion of the device planarization layer 130 is removed. For example, an air-gap can be formed inside the separating trench ST. The light-emitting unit 320 of each pixel area PA can be partially separated from the light-emitting unit 320 of adjacent pixel area PA by the separating trench ST. For example, the light-emitting unit 320 of each pixel area PA can include emission stacks and at least one charge generation layer disposed between the emission stacks, the at least one charge generation layer disposed on each pixel area PA can be separated from the at least one charge generation layer disposed on adjacent pixel area PA by the separating trench ST. Thus, in the display apparatus according to the embodiment of the present disclosure, the leakage of the driving current through the at least one charge generation layer can be prevented.

An encapsulation structure 400 can be disposed on the light-emitting device 300 of each pixel area PA. The encapsulation structure 400 can prevent the damage of the light-emitting device 300 in each pixel area PA due to external impact and moisture. A thickness difference due to the light-emitting device 300 of each pixel area PA can be removed by the encapsulation structure 400. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can include an inorganic insulating material, and the second encapsulating layer 420 can include an organic insulating material. An upper surface of the encapsulation structure 400 opposite to the device substrate 100 can be flat.

Color filters 500B, 500R and 500G can be disposed on the encapsulation structure 400. Each of the color filters 500B, 500R and 500G can overlap the emission area B-EA, R-EA and G-EA of one of the pixel areas PA. Each of the color filters 500B, 500R and 500G can include a different material from the color filter 500B, 500R and 500G adjacent in the first direction X. The light passing through the color filter 500B, 500R and 500G of each pixel area PA can display a same color as the light emitted by the micro-cavity structure formed in the corresponding pixel area PA. For example, the color filters 500B, 500R and 500G can include a blue color filter 500B overlapping with the blue emission area B-EA, a red color filter 500R overlapping with the red emission area R-EA, and a green color filter 500G overlapping with the green emission area G-EA. The blue color filter 500B, the red color filter 500R and the green color filter 500G can be repeatedly arranged in the first direction X. Each of the blue color filter 500B, the red color filter 500R and the green color filter 500G can extend in the second direction Y. Thus, in the display apparatus according to the embodiment of the present disclosure, the color reproducibility of each pixel area PA can be improved.

The color filters 500B, 500R and 500G can be disposed side by side in the first direction X. Each of the color filters 500B, 500R and 500G can have a same size as the corresponding emission area B-EA, R-EA and G-EA. For example, each color filter 500B, 500R and 500G can be spaced apart from the color filter 500B, 500R and 500G adjacent in the first direction X. A black matrix 510 can be disposed between the color filters 500B, 500R and 500G adjacent in the first direction X. Thus, in the display apparatus according to the embodiment of the present disclosure, the light emitted from the emission area B-EA, R-EA and G-EA of each pixel area PA toward the color filter 500B, 500R and 500G of adjacent pixel area PA can be blocked by the black matrix 510. Therefore, in the display apparatus according to the embodiment of the present disclosure, the unintended color mixing can be prevented.

An optical planarization layer 600 can be disposed on the color filters 500B, 500R and 500G and the black matrix 510. The optical planarization layer 600 can prevent the damage of the color filters 500B, 500R and 500G due to the external impact. The optical planarization layer 600 can include an insulating material. The optical planarization layer 600 can include a transparent material. For example, the optical planarization layer 600 can be an organic insulating layer made of an organic insulating material.

The display apparatus according to the embodiment of the present disclosure can include a diode substrate 700 and light-emitting diodes 800. The diode substrate 700 can be disposed on a lower surface of the device substrate 100 opposite to the upper surface of the device substrate 100. The light-emitting diodes 800 can be disposed side by side on an upper surface of the diode substrate 700 toward the device substrate 100. For example, in the display apparatus according to the embodiment of the present disclosure, the diode substrate 700 can be a first substrate, and the device substrate 100 can be a second substrate disposed on the first substrate. Various signal wirings to control the light-emitting diodes 800 can be formed in the diode substrate 700. For example, the diode substrate 700 can be a printed circuit board (PCB) including signal wirings. The light-emitting diodes 800 can be mounted on the upper surface of the diode substrate 700. Each of the light-emitting diodes 800 can emit light displaying a specific color. The light emitted from each light-emitting diode 800 can display a different color from the light emitted from the emission areas B-EA, R-EA and G-EA. For example, each of the light-emitting diodes 800 can emit white light.

The light-emitting diodes 800 can be disposed between the emission areas B-EA, R-EA and G-EA. For example, each of the light-emitting diodes 800 can overlap the separating trench ST. Each of the light-emitting diodes 800 can have a same size as the separating trench ST. The light-emitting diodes 800 cannot or may not overlap the color filters 500B, 500R and 500G. For example, each of the light-emitting diodes 800 can be disposed between the emission areas B-EA, R-EA and G-EA adjacent in the first direction X. For example, in the display apparatus according to the embodiment of the preset disclosure, the light-emitting diodes 800 can be disposed side by side on the diode substrate 700 in the first direction X, and each of the light-emitting diodes 800 can overlap a region between the emission areas B-EA, R-EA and G-EA adjacent in the first direction X. A length of each light-emitting diode 800 in the first direction X can be the same as a width of the separating trench ST in the first direction X. A length of each light-emitting diode 800 in the second direction Y can be smaller than a length of each emission area B-EA, R-EA and G-EA in the second direction Y. For example, each of the light-emitting diodes 800 can be spaced apart from the light-emitting diode 800 adjacent in the second direction Y.

The device substrate 100 can include substrate holes 100h overlapping with the light-emitting diodes 800. Thus, in the display apparatus according to the embodiment of the present disclosure, the light emitted from each light-emitting diode 800 can pass through one of the substrate holes 100h. Each of the substrate holes 100h can completely penetrate the device substrate 100. A side-wall of each substrate hole 100h can be covered by the insulating patterns 100b. The device driving circuit DC of each pixel area PA can be disposed between the substrate holes 100h. Therefore, in the display apparatus according to the embodiment of the present disclosure, the leakage of the driving current generated by the device driving circuit DC of each pixel area PA through the device substrate 100 can be effectively prevented.

One of the reflective electrodes 200B, 200R and 200G disposed between the device driving circuit DC and the light-emitting device 300 of each pixel area PA can include openings 200h overlapping with the substrate holes 100h. For example, in the display apparatus according to the embodiment of the present disclosure, the openings 200h can be formed in the red reflective electrode 200R disposed close to the device substrate 100. The openings 200h formed in red reflective electrode 200R can overlap the separating trench ST. Thus, in the display apparatus according to the embodiment of the present disclosure, the light passing through each substrate hole 100h can travel toward the separating trench ST through one of the openings 200h formed in the red reflective electrode 200R. Further, in the display apparatus according to the embodiment of the present disclosure, the light passing through each substrate hole 100h and travelling toward adjacent light-emitting device 300 can be blocked by the reflective electrodes 200B, 200R and 200G. Therefore, in the display apparatus according to the embodiment of the present disclosure, the light by each light-emitting diode 800 can be emitted between the emission areas B-EA, R-EA and G-EA by the reflective electrode 200B, 200R and 200G. For example, in the display apparatus according to the embodiment of the present disclosure, the light by each light-emitting diode 800 cannot or may not be mixed with the light by the light-emitting device 300 of each pixel area PA.

The black matrix 510 can include penetrating holes 510h overlapping with the separating trench ST. For example, each of the light-emitting diodes 800 can overlap one of the penetrating holes 510h of the black matrix 510. Thus, in the display apparatus according to the embodiment of the present disclosure, the light passing through the openings 200h formed in one of the reflective electrodes 200B, 200R and 200G can be emitted outside through the penetrating holes 510h of the black matrix 510. The light passing through the separating trench ST and travelling toward the color filter 500B, 500R and 500G of adjacent pixel area PA can be blocked by the black matrix 510. Therefore, in the display apparatus according to the embodiment of the present disclosure, the unintended color mixing can be prevented. Each of the penetrating holes 510h can be filled by the optical planarization layer 600.

Accordingly, the display apparatus according to the embodiment of the present disclosure can comprise the light-emitting devices 300 disposed on the upper surface of the device substrate 100, and the light-emitting diodes 800 disposed on the lower surface of the device substrate 100, wherein each of the light-emitting devices 300 can overlap one of the emission areas B-EA, R-EA and G-EA, wherein each of the light-emitting diodes 800 can be disposed between the emission areas B-EA, R-EA and G-EA adjacent in the first direction X, wherein the white light emitted from each light-emitting diode 800 can be distinguished from the light emitted from the light-emitting devices 300 by the substrate holes 100h, the openings 200h of the red reflective electrode 200R and the penetrating holes 510h of the black matrix 510. Thus, in the display apparatus according to the embodiment of the present disclosure, the luminance of the image provided to the user can be improved by the white light emitted from the light-emitting diodes 800 as a whole.

In the display apparatus according to the embodiment of the present disclosure, the light by each light-emitting diode 800 can be emitted outside between the emission areas B-EA, R-EA and G-EA. For example, in the display apparatus according to the embodiment of the present disclosure, a portion of the region where the light is not generated by the light-emitting device 300 of each pixel area PA can be used as an emitting area DA where the light by the light-emitting diode 800 is emitted. Thus, in the display apparatus according to the embodiment of the present disclosure, the luminance of the image can be increased without the reduction in the area of the emission area B-EA, R-EA and G-EA defined in each pixel area PA. Therefore, in the display apparatus according to the embodiment of the present disclosure, the power consumption can be reduced.

The display panel DP can include a display area AA in which the pixel areas PA are disposed, and a bezel area BZ being disposed outside the display area AA. For example, the display area AA can be surrounded by the bezel area BZ. A gate driver electrically connected to the gate line GL, a data driver electrically connected to the data line DL, and a power unit electrically connected to the power voltage supply line PL can be disposed outside the display area AA. Thus, in the display apparatus according to the embodiment of the present disclosure, each of the signal wirings GL, DL and PL can include a region disposed on the bezel area BZ.

The display apparatus according to the embodiment of the present disclosure can include a substrate adhesive layer 900 disposed between the diode substrate 700 and the device substrate 100. For example, the light-emitting diodes 800 can be covered by the substrate adhesive layer 900. The substrate adhesive layer 900 can include an insulating material. The substrate adhesive layer 900 can include a transparent material. The substrate adhesive layer 900 can include an adhesive material. Thus, in the display apparatus according to the embodiment of the present disclosure, the diode substrate 700 in which the light-emitting diodes 800 are mounted can be attached to the lower surface of the device substrate 100 by the substrate adhesive layer 900. Each of the substrate holes 100h can be filled by the substrate adhesive layer 900. Therefore, in the display apparatus according to the embodiment of the present disclosure, a gap between the diode substrate 700 and the device substrate 100 can be stably maintained.

The display apparatus according to the embodiment of the present disclosure is described that the device driving circuit DC of each pixel area PA consists of the first thin film transistor TR1, the second thin film transistor TR2 and the storage capacitor Cst. However, in the display apparatus according to another embodiment of the present disclosure, the device driving circuit DC of each pixel area PA can include a driving thin film transistor and at least one switching thin film transistor. For example, in the display apparatus according to another embodiment of the present disclosure, the device driving circuit DC of each pixel area PA can further include a third thin film transistor to initialize the storage capacitor Cst of the corresponding pixel area PA according to the gate signal. Thus, in the display apparatus according to another embodiment of the present disclosure, the degree of freedom in the configuration of each device driving circuit DC can be improved.

In the display apparatus according to the embodiment of the present disclosure, the location and the electric connection of the first drain electrode, the first source electrode, the second drain electrodes and the second source electrode of each device driving circuit DC can vary depending on the configuration of the corresponding device driving circuit DC and/or the type of the corresponding thin film transistors TR1 and TR2. For example, in the display apparatus according to another embodiment of the present disclosure, the second gate electrode of each device driving circuit DC can be electrically connected to the first drain electrode of the corresponding device driving circuit DC. Thus, in the display apparatus according to another embodiment of the present disclosure, the degree of freedom in the configuration of each device driving circuit DC and the type of each thin film transistor TR1 and TR2 can be improved.

The display apparatus according to the embodiment of the present disclosure is described that the device substrate 100 is a wafer formed of a semiconductor material, such as silicon. However, in the display apparatus according to another embodiment of the present disclosure, the device substrate 100 can include glass or plastic. For example, in the display apparatus according to another embodiment of the present disclosure, the device driving circuit DC of each pixel area PA can be formed on a buffer insulating layer covering the upper surface of the device substrate 100. The first thin film transistor TR1 and the second thin film transistor TR2 of each pixel area PA can include a semiconductor pattern made of a semiconductor material. Thus, in the display apparatus according to another embodiment of the present disclosure, the degree of freedom in the material of the device substrate 100 and the configuration of each device driving circuit DC can be improved.

The display apparatus according to the embodiment of the present disclosure is described where each of the light-emitting diodes 800 emits white light.

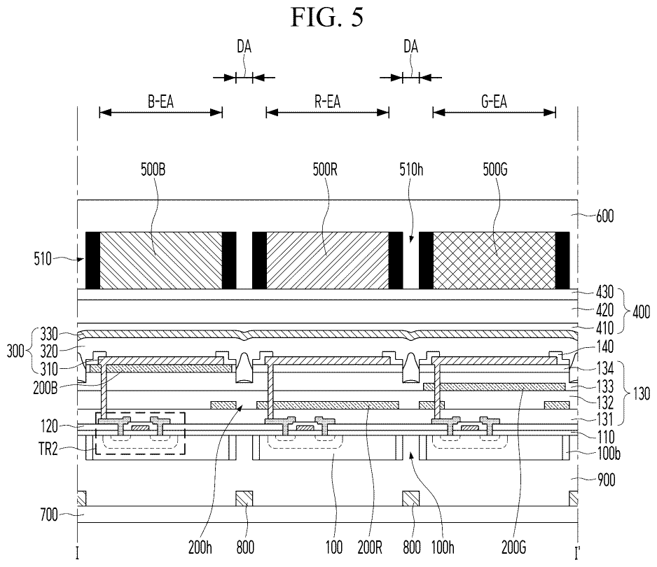

FIGS. 5 to 16 are views showing the display apparatus according to other embodiment(s) of the present disclosure.

In the display apparatus according to another embodiment of the present disclosure, the light emitted from each light-emitting diode 800 can display a same color as the light emitted one of the emission areas B-EA, R-EA and G-EA.

For example, in the display apparatus according to another embodiment of the present disclosure, each of the light-emitting diodes 800 can includes a same material as the blue color filter 500B, as shown in FIG. 5. The light emitted from each light-emitting diode 800 can be blue light displaying a same color as the light passing through the blue color filter 500B. Thus, in the display apparatus according to another embodiment of the present disclosure, the luminance and the amount of the light passing through the blue color filter 500B can be supplemented by the blue light emitted from each light-emitting diode 800. Therefore, in the display apparatus according to another embodiment of the present disclosure, the quality of the image provided to the user can be improved. Further, in the display apparatus according to another embodiment of the present disclosure, the color reproducibility of the image can be improved.

The display apparatus according to the embodiment of the present disclosure is described that the device substrate 100 includes the substrate holes 100h overlapping with the light-emitting diodes 800. However, in the display apparatus according to another embodiment of the present disclosure, the lower surface of the device substrate 100 can extend parallel to the upper surface of the device substrate 100.

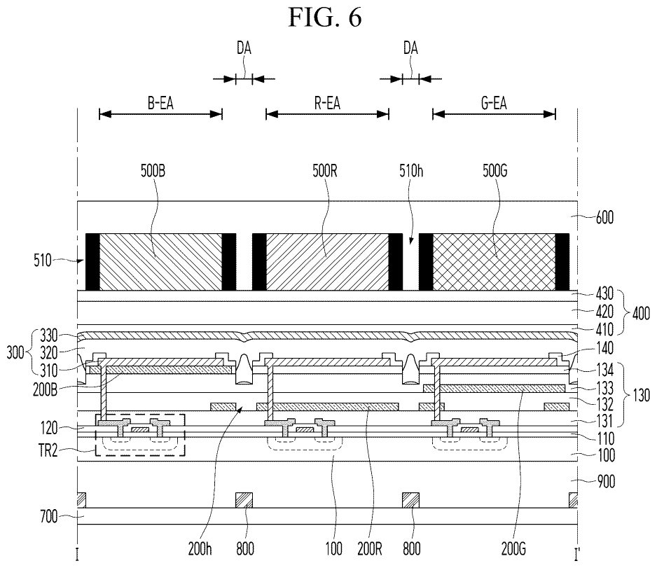

For example, in the display apparatus according to another embodiment of the present disclosure, the substrate holes cannot or may not be formed in the device substrate 100, as shown in FIG. 6. Thus, in the display apparatus according to another embodiment of the present disclosure, the occurrence of cracks due to a process of forming the substrate holes can be prevented. Therefore, in the display apparatus according to the embodiment of the present disclosure, the reliability of the device driving circuit DC in each pixel area PA can be improved.

The display apparatus according to the embodiment of the present disclosure is described that the black matrix 510 is disposed on a side surface of each color filter 500B, 500R and 500G. However, in the display apparatus according to another embodiment of the present invention, the black matrix 510 can be omitted.

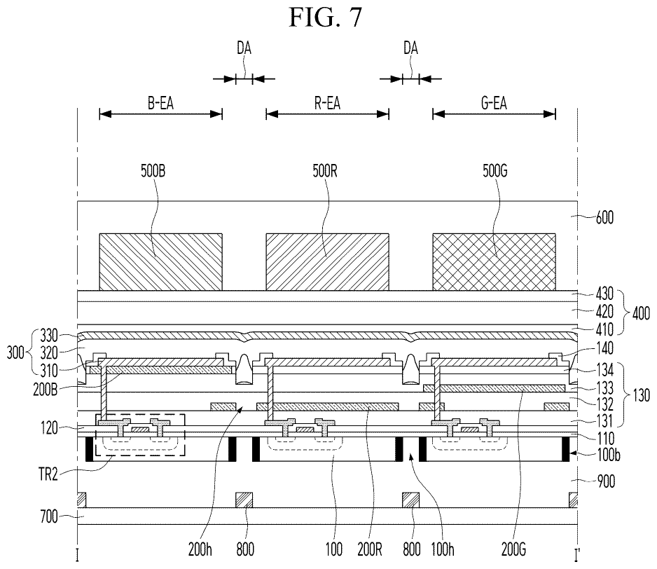

For example, in the display apparatus according to another embodiment of the present disclosure, the insulating patterns 100b covering the side-wall of each substrate hole 100h can include a light-blocking material, and a space between adjacent color filters 500B, 500R and 500G can be completely filled by the optical planarization layer 600, as shown in FIG. 7. The light-blocking material can mean a material that blocks light. For example, the light-blocking material can include a black dye, such as carbon black. Thus, in the display apparatus according to another embodiment of the present disclosure, a travelling direction of the light by each light-emitting diode 800 can be restricted by the insulating patterns 100b and the red reflective electrode 200R including the openings 200h. Therefore, in the display apparatus according to another embodiment of the present disclosure, the production energy can be reduced by process optimization.

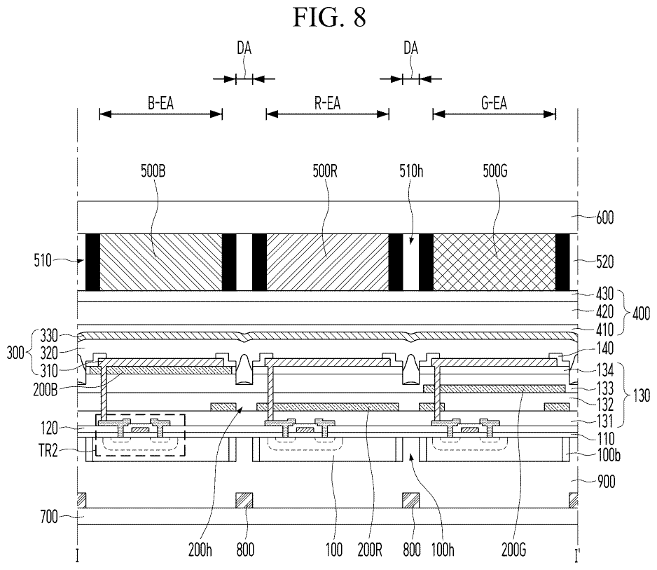

In the display apparatus according to another embodiment of the present disclosure, the penetrating holes 510h of the black matrix 510 can be filled by light-transmitting patterns 520, as shown in FIG. 8. The light-transmitting patterns 520 can include a material having a higher transmittance than the optical planarization layer 600. Thus, in the display apparatus according to another embodiment of the present disclosure, the degree of freedom in the material of the optical planarization layer 600 can be improved.

The display apparatus according to the embodiment of the present disclosure is described that one of the reflective electrode 200B, 200R and 200G includes the openings 200 h overlapping with the light-emitting diodes 800. However, in the display apparatus according to another embodiment of the present disclosure, conductive pattern including the openings 200h can be disposed between the first planarization layer 131 and the reflective electrodes 200B, 200R and 200G.

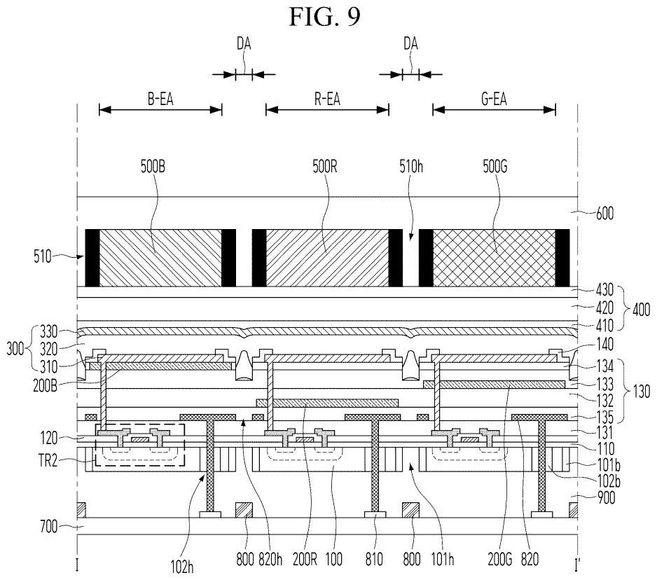

For example, in the display apparatus according to another embodiment of the present disclosure, conductive patterns 820 including openings 820h can be disposed between the first planarization layer 131 and the second planarization layer 132, and the reflective electrodes 200B, 200R and 200G can be disposed between a fifth planarization layer 135 covering the conductive patterns 820 and the second planarization layer 132, as shown in FIG. 9. Each of the openings 820h can overlap one of the light-emitting diodes 800. Thus, in the display apparatus according to another embodiment of the present disclosure, the light emitted from each light-emitting diode 800 can pass through one of the openings 820h. Therefore, in the display apparatus according to another embodiment of the present disclosure, the damage of the reflective electrode 200B, 200R and 200G due to a process of forming the openings 802h can be prevented.

In the display apparatus according to another embodiment of the present disclosure, diode driving parts 810 can be disposed on the upper surface of the diode substrate 700 toward the device substrate 100. The operation of each light-emitting diode 800 can be controlled by one of the diode driving parts 810. For example, each of the diode driving parts 810 can be electrically connected to one of the light-emitting diodes 800. The diode driving parts 810 can be covered by the substrate adhesive layer 900.

Each of the conductive patterns 820 can be electrically connected to one of the diode driving parts 810. For example, the device substrate 100 can include substrate holes 101h overlapping with the light-emitting diodes 800 and connection holes 102h overlapping with the conductive patterns 820, first insulating patterns 101b can be disposed on a side-wall of each substrate hole 101h, and second insulating patterns 102b can be disposed on a side-wall of each connection hole 102h. Each of the conductive patterns 820 can be connected to the corresponding diode driving parts 810 by passing through one of the connection holes 102h. For example, in the display apparatus according to another embodiment of the present disclosure, the conductive patterns 820 can be used as signal wirings to transmit signals to the diode driving parts 810. The device substrate 100 can be insulated from the conductive patterns 820 by the second insulating patterns 102b. Thus, in the display apparatus according to another embodiment of the present disclosure, the degree of freedom in the structure can be improved.

The display apparatus according to the embodiment of the present disclosure is described that the substrate adhesive layer 900 has a single-layer structure. However, in the display apparatus according to another embodiment of the present disclosure, the substrate adhesive layer 900 can have a multi-layer structure.

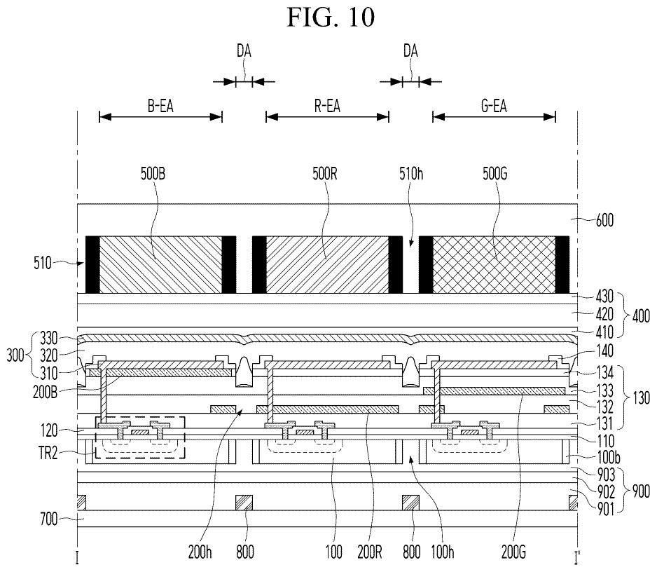

For example, in the display apparatus according to another embodiment of the present disclosure, the substrate adhesive layer 900 can have a stacked structure of a first adhesive layer 901, a second adhesive layer 902 and a third adhesive layer 903, as shown in FIG. 10. The light-emitting diodes 800 can be covered by the first adhesive layer 901. The substrate holes 100h can be filled by the third adhesive layer 903. The third adhesive layer 903 can be attached to the first adhesive layer 901 by the second adhesive layer 902. Thus, in the display apparatus according to another embodiment of the present disclosure, the diode substrate 700 in which the light-emitting diodes 800 are mounted can be stably coupled to the lower surface of the device substrate 100.

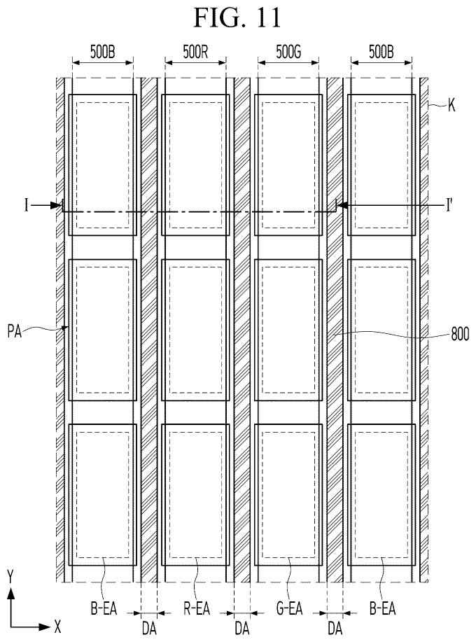

The display apparatus according to the embodiment of the present disclosure is described that each of the light-emitting diodes 800 is spaced apart from the light-emitting diode 800 adjacent in the second direction Y. However, in the display apparatus according to another embodiment of the present disclosure, each of the light-emitting diodes 800 can extend between the emission areas B-EA, R-EA and G-EA in the second direction Y, as shown in FIG. 11. Thus, in the display apparatus according to another embodiment of the present disclosure, the light emitted from each light-emitting diode 800 can be increased. Therefore, in the display apparatus according to another embodiment of the present disclosure, the luminance and the quality of the image can be effectively improved.

The display apparatus according to the embodiment of the present disclosure is described that each of the light-emitting diodes 800 is disposed on side-surfaces of the emission areas B-EA, R-EA and G-EA extending in the second direction Y. However, in the display apparatus according to another embodiment of the present disclosure, the light-emitting diodes 800 cannot or may not overlap the emission areas B-EA, R-EA and G-EA in the first direction X and in the second direction Y.

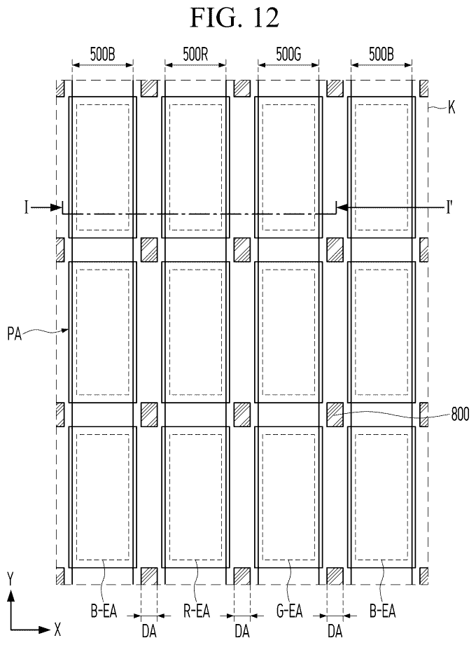

For example, in the display apparatus according to another embodiment of the present disclosure, each of the light-emitting diodes 800 can be disposed between the emission areas B-EA, R-EA and G-EA adjacent in an inclined direction with respect to the first direction X and the second direction Y, as shown in FIG. 12. For example, in the display apparatus according to another embodiment of the present disclosure, the light-emitting diodes 800 can be disposed to correspond to corners of each emission area B-EA, R-EA and G-EA.

A length of each light-emitting diode 800 in the first direction X can be smaller than a distance between the emission areas B-EA, R-EA and G-EA adjacent in the first direction X. A length of each light-emitting diode 800 in the second direction Y can be smaller than a distance between the emission areas B-EA, R-EA and G-EA adjacent in the second direction Y. Thus, in the display apparatus according to another embodiment of the present disclosure, the interference of the light emitted from each light-emitting diode 800 and the light emitted from the emission area B-EA, R-EA and G-EA adjacent the corresponding light-emitting diode 800 can be significantly reduced.

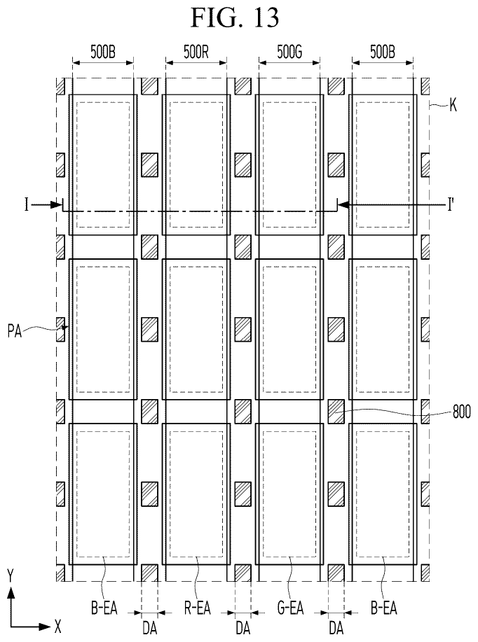

In the display apparatus according to another embodiment of the present disclosure, the light-emitting diodes 800 can be arranged to have a predetermined interval in the first direction X and in the second direction Y, as shown in FIG. 13. Thus, in the display apparatus according to the embodiment of the present disclosure, the overall luminance can be uniformly increased by the light-emitting diodes 800. Therefore, in the display apparatus according to the embodiment of the present disclosure, the occurrence of stains due to a luminance deviation can be prevented.

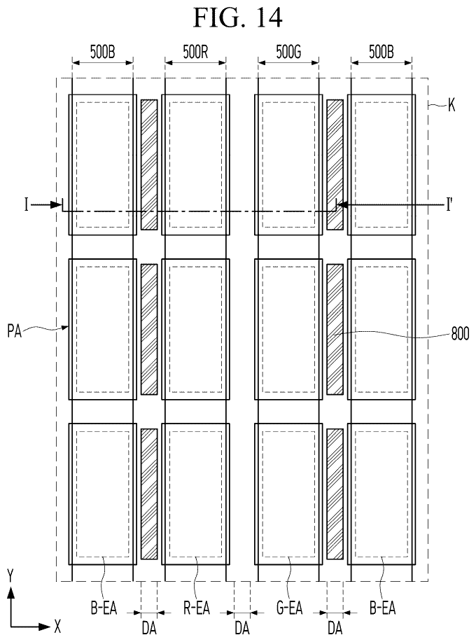

In the display apparatus according to another embodiment of the present disclosure, the light-emitting diodes 800 can be disposed only in some of regions between the emission areas B-EA, R-EA and G-EA adjacent in the first direction X, as shown in FIG. 14. Thus, in the display apparatus according to the embodiment of the present disclosure, a process for a path of the light emitted from the light-emitting diodes 800 can be simplified. Therefore, in the display apparatus according to the embodiment of the present disclosure, the production energy can be reduced by process optimization.

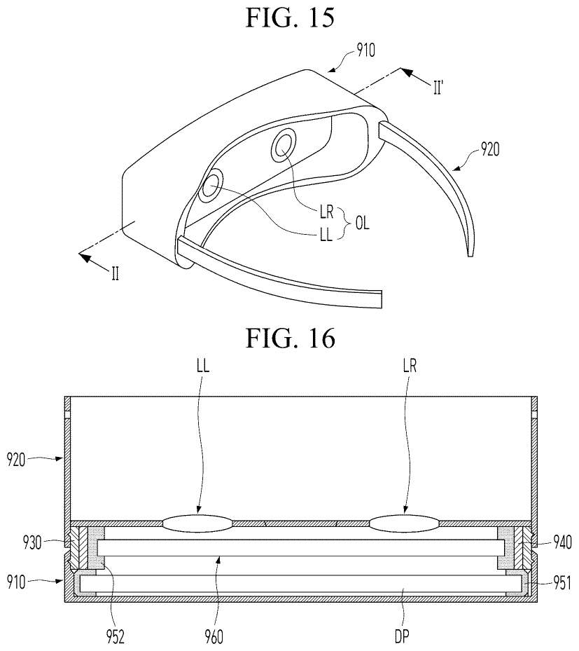

In the display apparatus according to another embodiment of the present disclosure, the display panel DP can be used in various electronic devices. For example, the display apparatus according to another embodiment of the present disclosure can be a head mounted display (HMD) apparats in which the display panel DP is accommodated in an image element 910 and the image element 910 is fixed in front of the user's eyes by a mounting element 920, as shown in FIGS. 15 and 16. The mounting element 920 can have a shape, such as a leg of a spectacle frame. For example, the mounting element 920 can have a shape extending in a direction from an edge of the image element 910. The mounting element 920 can be coupled to the image element 910 by a coupling element 930. For example, the coupling element 930 can have a plate shape including a region coupled to the image element 910 and a region coupled to the mounting element 920. The coupling element 930 can be disposed inside the image element 910 and the mounting element 920.

The eyepiece lenses OL disposed on a side of the image element 910 can include a left-eye lens LL disposed in front of the user's left eye, and a right-eye lens LR disposed in front of the user's right eye. An empty space can be disposed between the display panel DP and the eyepiece lenses OL. For example, the display panel DP can be disposed close to a first surface of the image element 910, and the left-eye lens LL and the right-eye lens LR can be fixed at a second surface of the image element 910 opposite to the first surface of the image element 910. A gap maintaining element 940 can be disposed inside the coupling element 930 to maintain a space between the display panel DP and the eyepiece lenses OL. The gap maintaining element 940 can be disposed parallel to the coupling element 930. For example, the gap maintaining element 940 can be in direct contact with the coupling element 930.

A first fixing element 951 to fix the display panel DO can be disposed in the image element 910. For example, the first fixing element 951 can be in direct contact with the first surface of the image element 910. Thus, in the display apparatus according to another embodiment of the present disclosure, the movement of the display panel DP and the eyepiece lenses OL according to the user's movement can be effectively prevented. Therefore, in the display apparatus according to another embodiment of the present disclosure, the visibility of the image recognized by the user can be improved.

In the display apparatus according to another embodiment of the present disclosure, the image by the display panel DP and an actual object disposed beyond the first surface of the image element 910 can be provided simultaneously to the user. For example, at least one optical lens 960 can be disposed between the display panel DP and the eyepiece lenses OL. The at least one optical lens 960 can be spaced apart from the display panel DP and the eyepiece lens OL. For example, a second fixing element 952 to fix the at least one optical lens 960 can be disposed in the image element 910. The image by the display panel DP can be displayed on an actual object disposed in front of the user by the at least one optical lens 960. Thus, in the display apparatus according to another embodiment of the present disclosure, an accident due to blocking the user's view can be prevented.

The display apparatus according to another embodiment of the present disclosure is described that the mounting element 920 has a shape, such as a leg of a spectacle frame. However, in the display apparatus according to another embodiment of the present disclosure, the mounting element 920 can have various shapes. For example, in the display apparatus according to another embodiment of the present disclosure, the mounting element 920 can have a head gear shape surrounding the user's head. Thus, in the display apparatus according to another embodiment of the present disclosure, the degree of freedom in a type of the electronic devices in which the display panel DP is used can be improved.

As a result, the display apparatus according to the embodiments of the present disclosure can comprise a second substrate disposed on a first substrate, light-emitting diodes disposed side by side on a surface of the first substrate toward the second substrate, and light-emitting devices disposed on a surface of the second substrate opposite to the first substrate, wherein the second substrate can include emission areas overlapping with the light-emitting devices, and wherein each of the light-emitting diodes can be disposed between the emission areas adjacent in the first direction.

Thus, in the display apparatus according to the embodiments of the present disclosure, the image provided to the user can be generated by using the light emitted from each light-emitting device and/or the light emitted from each light-emitting diode.

Accordingly, in the display apparatus according to the embodiments of the present disclosure, the overall luminance of the image can be improved. Further, in the display apparatus according to the embodiments of the present disclosure, the low power driving can be possible, and the power consumption can be reduced.

The present disclosure being thus described, it will be obvious that the same may be varied in many ways. Such variations are not to be regarded as a departure from the spirit and scope of the present disclosure, and all such modifications as would be obvious to one skilled in the art are intended to be included within the scope of the following claims.

What is claimed is:

1. A display apparatus comprising:
light-emitting diodes disposed side by side on a first substrate in a first direction;
a second substrate on the light-emitting diodes, the second substrate including emission areas; and
light-emitting devices on the second substrate, the light-emitting devices overlapping with the emission areas,
wherein the emission areas are disposed side by side in the first direction and in a second direction perpendicular to the first direction, and
wherein each of the light-emitting diodes is disposed between adjacent emission areas disposed in the first direction.

2. The display apparatus according to claim 1, wherein each of the emission areas realizes a different color from an adjacent emission area disposed in the first direction.

3. The display apparatus according to claim 1, wherein the second substrate further includes substrate holes disposed between the emission areas, and
wherein each of the light-emitting diodes overlaps one of the substrate holes.

4. The display apparatus according to claim 3, further comprising a substrate adhesive layer disposed between the light-emitting devices and the second substrate,
wherein the substrate holes are filled by the substrate adhesive layer.

5. The display apparatus according to claim 3, further comprising insulating patterns disposed on a side-wall of each of the substrate holes,
wherein each of the insulating patterns includes a light-blocking material.

6. The display apparatus according to claim 1, further comprising a planarization layer disposed between the second substrate and the light-emitting devices,
wherein the planarization layer includes at least one trench disposed between the emission areas, and
wherein each of the light-emitting diodes overlaps the at least one trench.

7. The display apparatus according to claim 1, further comprising color filters disposed on the light-emitting devices,
wherein each of the color filters overlaps one of the emission areas, and
wherein each of the color filters is spaced apart from an adjacent color filter disposed in the first direction.

8. The display apparatus according to claim 7, further comprising a black matrix disposed between the adjacent color filters disposed in the first direction,
wherein the black matrix includes penetrating holes overlapping with the light-emitting diodes.

9. The display apparatus according to claim 1, further comprising conductive patterns disposed between the second substrate and the light-emitting devices,
wherein at least one of the conductive patterns includes an opening overlapping with the light-emitting diodes.

10. The display apparatus according to claim 9, further comprising device driving circuits disposed between the second substrate and the light-emitting devices,
wherein each of the device driving circuits is electrically connected to one of the light-emitting devices, and
wherein the conductive patterns are insulated from the device driving circuits.

11. The display apparatus according to claim 9, further comprising diode driving parts disposed between the first substrate and the second substrate,
wherein the diode driving parts are spaced apart from the light-emitting diodes, and
wherein each of the diode driving parts is electrically connected to one of the light-emitting diodes and one of the conductive patterns.

12. The display apparatus according to claim 11, wherein the second substrate includes connection holes overlapping with the conductive patterns, and
wherein each of the conductive patterns is connected to the corresponding diode driving part passing through one of the connection holes.

13. The display apparatus according to claim 1, wherein a color displayed by light emitted from each light-emitting diode is different from colors displayed from the emission areas.

14. The display apparatus according to claim 1, further comprising:
a device planarization layer disposed between the second substrate and the light-emitting devices; and
fences disposed on the device planarization layer.

15. The display apparatus according to claim 14, wherein the device planarization layer includes at least one trench disposed between the emission areas.

16. The display apparatus according to claim 14, wherein a separation trench is disposed between the fences.
